(19) United States
(12) Patent Application Publication
(10) Pub. No.: US 2016/0211140 A1
(43) Pub. Date: Jul. 21, 2016

(54) Method for Processing a Semiconductor Surface

(71) Applicant: Infineon Technologies AG, Neubiberg (DE)

(72) Inventors: Jens Peter Konrath, Villach (AT); Ronny Kern, Finkenstein (AT); Stefan Krivec, Arnoldstein (AT); Ulrich Schmid, Wien (AT); Laura Stoeber, Wien (AT)

(21) Appl. No.: 14/997,221

(22) Filed: Jan. 15, 2016

(30) Foreign Application Priority Data
Jan. 16, 2015 (DE) 102015200673.5
Feb. 12, 2015 (DE) 102015102055.6

(51) Int. Cl. H01L 21/285; H01L 21/265; H01L 29/47

(52) U.S. Cl. CPC H01L 21/28537; H01L 29/47; H01L 21/26513

(57) ABSTRACT

A method for processing a semiconductor includes irradiating a surface of a semiconductor with ions of a first gas type for cleaning the surface and implanting of ions of a second gas type in a region below the surface of the semiconductor for creating defects in the region below the surface. The irradiating and the implanting are performed within the same chamber.

### PRIORITY CLAIM

This application claims priority to German Patent Application No. 10 2015 200 673.5 filed on 16 Jan. 2015 and to German Patent Application No. 10 2015 102 055.6 filed on 12 Feb. 2015, the content of both of said applications incorporated herein by reference in its entirety.

### TECHNICAL FIELD

Embodiments of the present invention relate to a method for processing a semiconductor surface.

### BACKGROUND

A Schottky diode is a unipolar device which may be used in a variety of electronic applications, in particular, power electronic applications. As compared to a bipolar diode, a Schottky diode has lower conduction losses and switches faster. The conduction losses of a diode are substantially proportional to a voltage drop across the diode when the diode is forward biased. In a silicon bipolar diode such voltage drop is usually between 0.6 and 0.7V, while a silicon Schottky diode usually features only between 0.15 and 0.45V.

A Schottky diode includes a metal-semiconductor junction between a metal (such as aluminium) and a semiconductor (such as silicon). The metal is selected such that the metal-semiconductor junction is a rectifying junction. Such metal can be referred to as Schottky metal.

When the Schottky metal and semiconductor are isolated from each other, the position of the Fermi level in the metal and the Fermi level in the semiconductor have different energy values. The Fermi level is the highest occupied energy state in a material at zero temperature. When the Schottky metal and the semiconductor are brought into contact charge carriers diffuse between the metal and the semiconductor until the Fermi levels are the same in the Schottky metal and the semiconductor. The rectifying behaviour of a metal-semiconductor contact depends on the height of a barrier (the so-called Schottky barrier) at the junction between the Schottky metal and the semiconductor. The height of the Schottky barrier is defined as the difference between the work function of the metal (the work function is the energy required to free an electron at the Fermi level of the metal) and the electron affinity of the semiconductor (the electron affinity is the difference between the energy of a free electron and the conduction band edge of the semiconductor).

In order to reduce conduction losses in a Schottky diode it may be desirable to reduce the height of the Schottky barrier so as to reduce the forward voltage drop.

There is a need to provide a method for processing a semiconductor surface in order to modify a Schottky barrier height in a Schottky diode which includes such surface.

### SUMMARY

One embodiment relates to a method for processing a semiconductor surface. The method comprises irradiating a surface of a semiconductor with ions of a first gas type for cleaning the surface and implanting ions of a second gas type in a region below the surface of the semiconductor for creating defects in the region below the surface. Irradiating the surface with ions of the first gas type and implanting the ions of the second gas type is thereby performed within the same chamber.

Those skilled in the art will recognize additional features and advantages upon reading the following detailed description and on viewing the accompanying drawings.

### BRIEF DESCRIPTION OF THE DRAWINGS

Examples will now be explained with reference to the drawings. The drawings serve to illustrate the basic principle, so that only aspects necessary for understanding the basic principle are illustrated. The drawings are not to scale. In the drawings the same reference characters denote like features.

FIG. 1 illustrates a vertical cross-sectional view of a Schottky diode.

FIG. 2 illustrates various energy levels for metals and semiconductors.

FIG. 3 illustrates an energy band diagram for a conventional metal-semiconductor junction.

FIG. 4 illustrates an energy band diagram for a metal-semiconductor junction with reduced Schottky barrier height.

FIG. 5 illustrates one example of an apparatus for processing a semiconductor surface.

FIG. 6 illustrates another example of an apparatus for processing a semiconductor surface.

FIG. 7 illustrates yet another example of an apparatus for processing a semiconductor surface.

FIGS. 8A-8C illustrate vertical cross-sectional views of a semiconductor body that illustrate one example of a method for processing a semiconductor surface.

### DETAILED DESCRIPTION

In the following detailed description, reference is made to the accompanying drawings, which form a part thereof, and in which are shown by way of illustration specific embodiments in which the invention may be practiced.

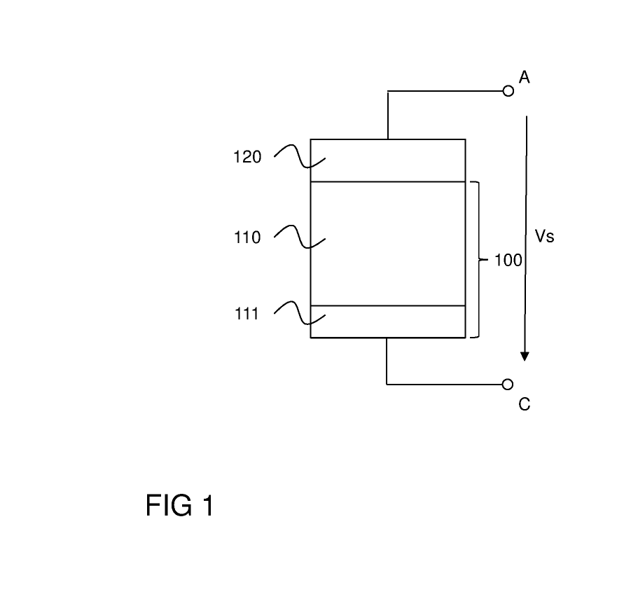

FIG. 1 schematically illustrates a vertical cross sectional view of a Schottky diode. The Schottky diode includes a Schottky contact (metal-semiconductor junction) between a metal region (metal layer) 120 and a semiconductor region (semiconductor layer) 100. The semiconductor region 100 may include differently doped sections. In the embodiment shown in FIG. 1, the semiconductor region 100 includes a first semiconductor region 110 adjoining the metal region 120, and a second semiconductor region 111 adjoining the first semiconductor region 110. The first semiconductor region 110 and the second semiconductor region 111 have the same conduction type (doping type) such as an n-type. The first semiconductor region 110 may have a lower doping concentration than the second semiconductor region 111. When Si is used as semiconductor material, the doping concentration of the first semiconductor region 110 is, for example, between 1E13 and 1E15 cm⁻³, the doping concentration of the second semiconductor region 111 is, for example, between 1E19 and 1E12 cm⁻³. The doping concentrations may be different for different semiconductor materials. For SiC, for example, the doping concentration of the first semiconductor region 110 is, for example, between 1E14 and 5E16 cm⁻³ and the doping concentration of the second semiconductor region 111 is, for example, between 1E17 and 1E20 cm⁻³. The first semiconductor region 110 forms a drift region (base region) of the Schottky diode and the second semiconductor region 111 forms an emitter region.

Referring to FIG. 1, the metal region 120 forms an anode of the diode and may be coupled to an anode terminal A and the second semiconductor region 111 forms a cathode of the diode and may be coupled to a cathode terminal C. The Schottky contact (Schottky junction) between the metal region 120 and the semiconductor region 100 is a rectifying contact, that is, a current flow through the Schottky diode is dependent on the polarity of a voltage Vs applied between the anode and cathode terminal. When the voltage Vs is positive (has the polarity as shown in FIG. 1) the Schottky junction is forward biased and a current flows when the voltage level reaches a Schottky barrier height of the Schottky junction. This is explained in further detail below. When the voltage Vs is negative the Schottky junction is reverse biased and prevents a current flow unless the level of the negative voltage reaches as breakthrough level. However, such breakthrough level is, inter alia, dependent on a doping concentration of the base region 110 and a length of the base region 110 in a current flow direction and can be up to several 10V or even up to several 100V.

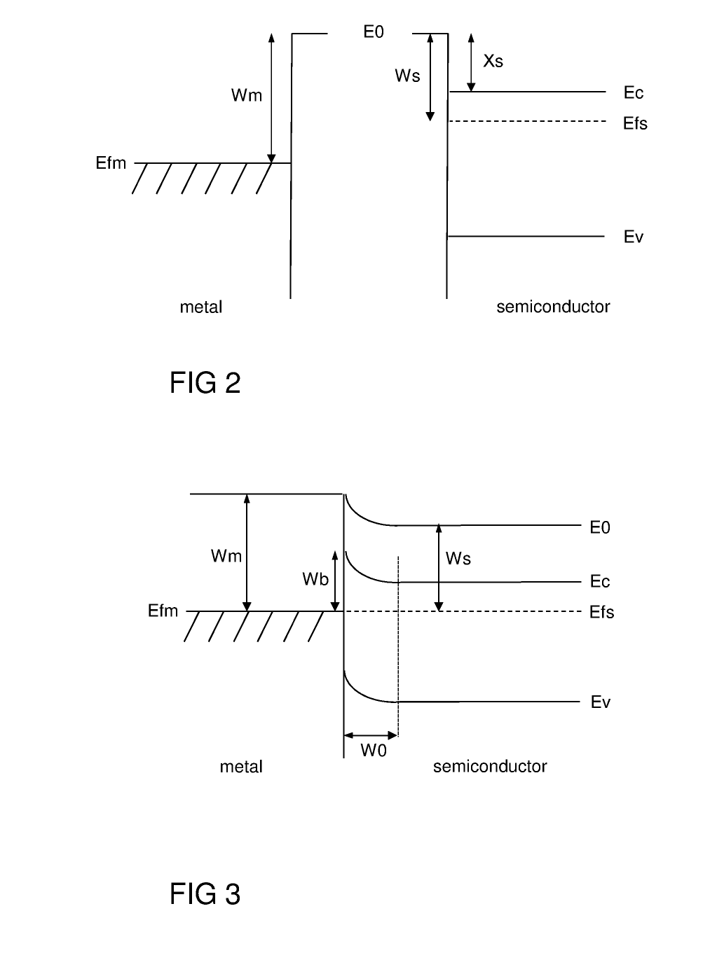

FIG. 2 illustrates the energy levels for a metal and an n-type semiconductor when separated from each other. The Fermi level Efm of the metal is different from the Fermi level Efs of the semiconductor. This means that the average energy of an electron added to the metal is not the same as the average energy of an electron added to the semiconductor. The work function Wm for the metal is defined as the energy required to move an electron from the Fermi level Efm position in the metal to a state of rest in free space E0 outside the surface of the metal. In the same manner, the work function Ws for the semiconductor is defined as the energy required to move an electron from the Fermi level Efs position in the semiconductor to a state of rest in free space E0 outside the surface of the semiconductor. Since no electrons are located at the Fermi level Efs position in the semiconductor, an electron affinity Xs for the semiconductor is defined as the energy required to move an electron from the bottom of the conduction band Ec in the semiconductor to a state of rest in free space E0 outside the surface of the semiconductor. In the example illustrated in FIG. 2 the Fermi level Efm of the metal is lower than the Fermi level Efs of the semiconductor.

When metal and the semiconductor are brought in contact, electrons are transferred from the semiconductor to the metal due to their greater energy until a thermal equilibrium is established and the Fermi levels Efm, Efs are aligned. This transfer of electrons creates a negative charge in the metal and a positive charge within a depletion region W0 formed at the semiconductor surface. The resulting energy band diagram for a conventional metal-semiconductor junction is illustrated in FIG. 3.

When the metal and the semiconductor are in contact, the entire contact potential is supported within the depletion region W0. The formation of the depletion region W0 is associated with an electric field and so-called “band bending”. The band bending creates an energy barrier, the Schottky barrier Wb, that blocks further transfer of electrons into or out of the semiconductor. By reducing the height of the Schottky barrier Wb, the on-state voltage drop is decreased resulting in decreased conduction losses.

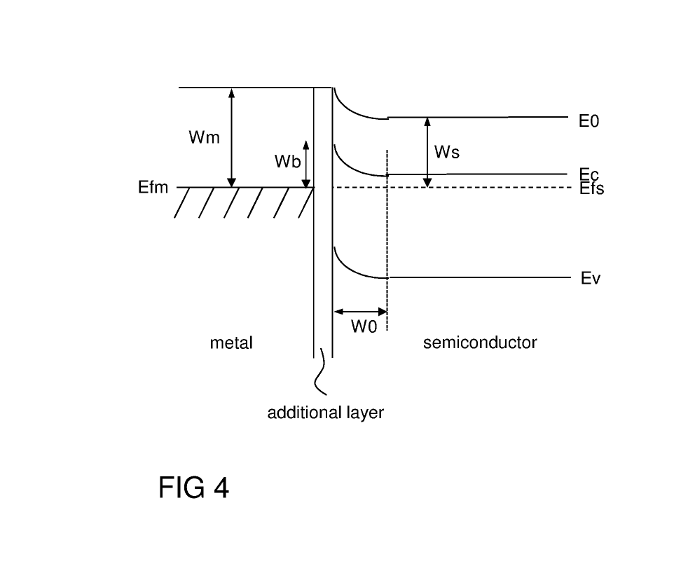

Therefore, it may be desirable to minimize the height of the Schottky barrier Wb in order to reduce conduction losses. This can be achieved by shifting the Fermi levels Efm, Efs such that they (almost) align with the conduction band Ec of the semiconductor. This can be achieved by inducing a shallow region of high doping concentration at the semiconductor surface proximate to the metal-semiconductor interface. The resulting energy band diagram for a metal-semiconductor junction with an additional layer having a high doping concentration is illustrated in FIG. 4. The Fermi levels Efm, Efs are therefore shifted closer to the conduction band Ec of the semiconductor and the height of the Schottky barrier Wb is reduced.

When an n-type semiconductor is used for the Schottky diode and the additional layer is a highly doped acceptor layer (p-type layer), a negative space charge region is formed, which leads to an increased depletion width in the n-type semiconductor resulting in an increased barrier height. Conversely, a highly doped donor layer (n-type layer) increases the surface electric field, leading to a reduction in the depletion width. This enhances the quantum mechanical tunnelling or thermionic field emission through the barrier, effectively lowering the barrier height. The barrier may be lowered to such an extent, that an ohmic contact may be formed between the semiconductor and the metal.

The additional layer may, for example, include a passivating material such as nitride, borane, oxide, hydride or fluoride. The material that is used may depend on the conduction type of the semiconductor. The additional layer may have a thickness of between approximately 0.1 nm and approximately 5 nm, for example. In a conventional process for forming a Schottky diode the additional layer is formed before cleaning the surface of the semiconductor and applying the metal layer. For this additional step the wafer needs to be transferred to a further processing machine, which increases the risk of defects.

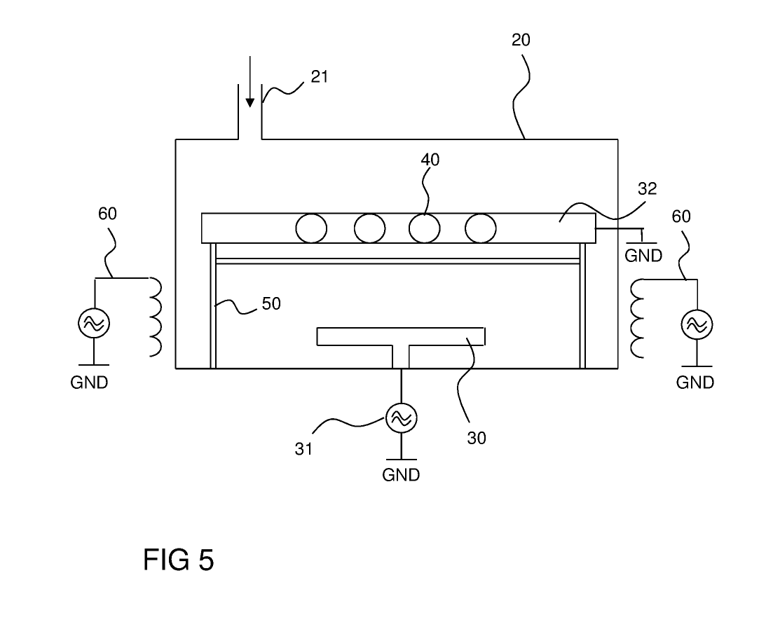

Residues, contaminants or the like might reduce the implantation dose by blocking the ions of the implantation species in a following implantation step, which will be described further below. To remove such residues or contaminants and clean the wafer surface, a back sputtering process may be performed. Further, by removing residues the adhesion of the metal to be sputtered may be increased and the series resistance may be lowered. During back sputtering, material is physically removed from the wafer surface by irradiating the wafer surface with ions of a first gas type. The ions may be generated in a plasma. An example of an apparatus for performing such a back sputtering process is illustrated in FIG. 5. The process is performed in a chamber 20, in particular a vacuum chamber. The chamber 20 has an inlet 21, through which gas can enter the chamber 20. A wafer may be positioned on a chuck 30, which is coupled to a high frequency voltage source 31. The high frequency voltage source 31 is further coupled to a terminal for reference potential GND. The chuck 30 functions as an electrode. A backplate electrode 32 that is coupled to a terminal for reference potential GND is positioned opposite to the chuck 30. A high-frequency alternating field is formed between the chuck 30 and the backplate electrode 32.

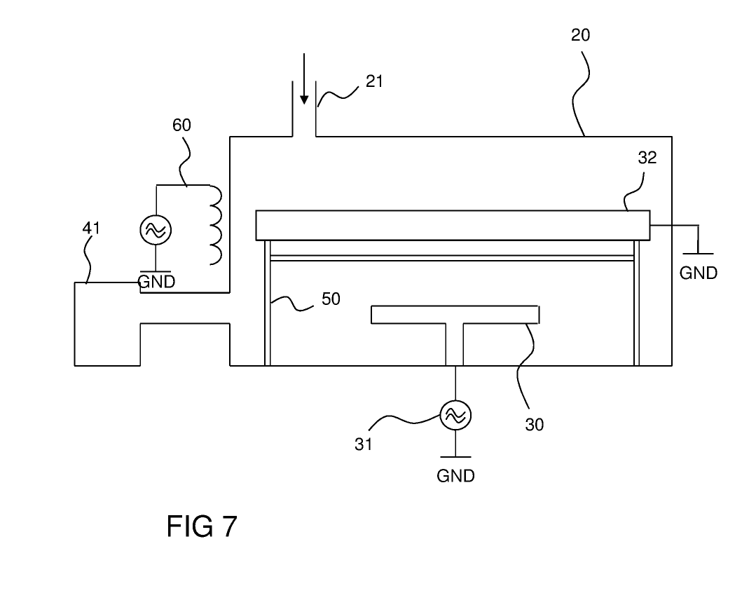

The efficiency of the process is affected by the temperature of the wafer. Therefore a heating unit 40 may be provided, that is configured to heat up the wafer. In the apparatus in FIG. 5, the heating unit 40 may include halogen lamps. The halogen lamps are integrated in the backplate electrode 32 and shine on the wafer positioned on the chuck 30. Using halogen lamps, however, is only an example. Another example of a heating unit 40 is illustrated in FIG. 7. In FIG. 7, the heating unit 40 comprises a microwave generator 41 coupled to the chamber 20. Any other suitable kind of heating unit 40 may, however, be used.

In order to generate a plasma, the apparatus comprises one or more ICP (Inductively Coupled Plasma) coils 60 that are arranged along the periphery of the chamber 20. The coils 60 may, however, also be arranged inside the chamber 20, in order to avoid heating of the walls of the chamber 20. A first gas, which may be a so called inert gas, is directed into the chamber 20 through the inlet 21. The first gas may be argon, neon or krypton, for example. By applying RF (radio frequency) power to the coils 60 an RF magnetic field is created inside the chamber 20. From the oscillating magnetic field of the ICP coils 60, electric currents are produced in the gas by electromagnetic induction. These currents heat up the gas which leads to an ionization of gas atoms.

Therefore, in the plasma that is provided between the chuck 30 and the backplate electrode 32, there are electrons and ionized gas atoms. The electrons and ionized gas atoms are accelerated alternately in both directions by the alternating electric field between the chuck 30 and the backplate electrode 32. With frequencies of more than 50 kHz (often a frequency of 13.56 MHz is used) the electrons and ionized gas atoms can no longer follow the alternating field. The electrons oscillate in the plasma area and collide with even more gas atoms. This results in even more ionized gas atoms. The ionized gas atoms move in the direction of the chuck 30, due to a superposed negative offset voltage. There they collide with the wafer and material is physically removed from the wafer surface. In the process convex structures are removed to a greater extent than planar structures. Further, the particles sputtered from the wafer surface reattach to the surface due to re-deposition. Thereby the surface of the wafer is planed during the process.

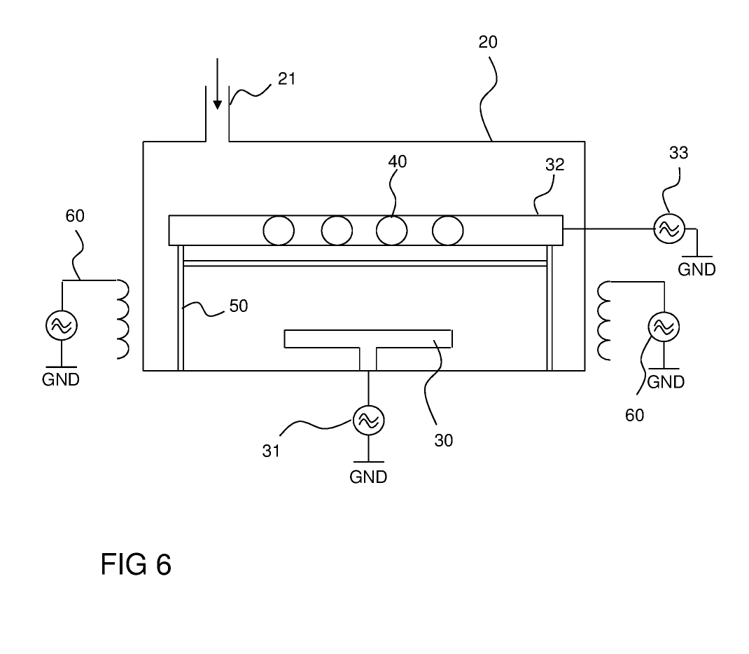

Instead of directly coupling the backplate electrode 32 to the terminal for reference potential GND, a further high frequency voltage source 33 may be coupled between the backplate electrode 32 and the terminal for reference potential GND, as is shown in FIG. 6. In this way a high frequency is specifically coupled into both electrodes 30, 32 and the potentials of both electrodes 30, 32 may be varied individually.

In order to protect the walls of the chamber 20 from material sputtered from the wafer surface, a spacer 50 may be arranged within the chamber 20. The spacer 50 may have a cylindrical or square shape, for example, when seen from above. The sidewalls of the spacer 50 thereby protect the sidewalls of the chamber. The spacer 50 may be (partially) open to the top, such that gas that enters the chamber 20 through the inlet 21 may flow into the space between the chuck 30 and the backplate electrode 32.

In conventional processes, the additional layer is implanted before or after cleaning the surface of the wafer. In conventional methods, the wafer is transferred to a further processing machine for this additional implantation step. According to one embodiment of the method disclosed herein, however, the implantation step is performed within the same processing machine as the back sputtering process. For this purpose, a second gas may be added to the first gas. Generally, the second gas includes one of n-type and p-type dopant atoms. For example, n-type dopants are included in nitrogen gas or phosphine, and p-type dopants are included in borane where boron is a p-type dopant. However, these are only examples. Any other gas that is suitable to implant an additional layer for reducing the Schottky barrier height may be added instead. The atoms of the second gas are, like the atoms of the first gas, accelerated in the direction of the wafer surface. The atoms of the second gas are impacted into the wafer, forming defects in a region below the surface of the semiconductor. They thereby alter the elemental composition of the semiconductor material (e.g. Si, GaN or GaAs) near the surface of the semiconductor. The height of the Schottky barrier is then no longer determined by the work function of the metal, but by the defects in the semiconductor instead. In this way, a thin additional layer is implanted during the back sputtering process and the wafer does not need to be transferred to a different processing machine for the implantation step. Instead of performing the two processes at the same time, it is also possible to perform the processes successively within the same chamber (20).

A following annealing step may also be performed within the same processing machine. Annealing, in general, is a heat treatment that alters the physical and (sometimes) chemical properties of a material to increase its ductility. It involves heating the material to a certain temperature and then the cooling of the material. Annealing can induce ductility, soften material, relieve internal stresses and refine the structure by making it homogenous.

Afterwards the Schottky metal (source material) may be sputtered on the wafer. The Schottky metal may be tungsten (W), titanium (Ti), molybdenum (Mo) or chromium (Cr), for example. The backplate electrode 32 may be covered with the source material, the so called target. As already described above, a plasma is provided between the chuck 30 and the target. The electrons and ionized gas atoms of the plasma are accelerated alternately in both directions by the alternating electric field between the chuck 30 and the backplate electrode 32. With frequencies of more than 50 kHz (often a frequency of 13.56 MHz is used) the electrons and ionized gas atoms can no longer follow the alternating field. The electrons oscillate in the plasma area and collide with even more gas atoms. This results in even more ionized gas atoms. The ionized gas atoms move in the direction of the backplate electrode 32, due to a superposed negative offset voltage. There they collide with the target and material is physically removed from the target. These atoms leave the target surface in all directions. The wafer that is positioned on the chuck 30 is then covered with an even metal coating.

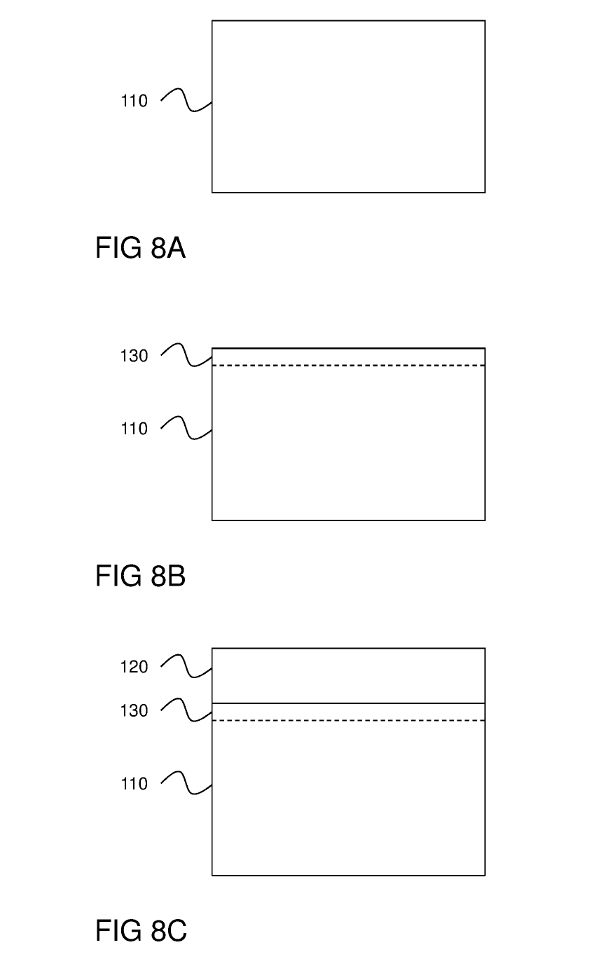

FIGS. 8A-8C illustrate an example of a method for processing a semiconductor surface in order to reduce the Schottky barrier height. In a first step a semiconductor is provided. The semiconductor may be a wafer or part of a wafer. FIG. 8A is a vertical cross-sectional view that shows the first semiconductor region 110 which forms the drift region (base region) of a Schottky diode. The first semiconductor region 110 has a first surface 101.

Referring to FIG. 8B, an additional layer 130 is formed in the first semiconductor region 110. The additional layer 130 extends from the first surface 101 into the first semiconductor region 110 in a vertical direction. The additional layer 130 may be formed in a way as has been explained above, by creating defects by means of implantation of gas ions.

Then referring to FIG. 8C, a metal layer 120 is formed on the semiconductor. The metal layer 120 adjoins the additional layer 130 and extends from the first surface 101 in a vertical direction. The metal layer may, for example, be sputtered on the first surface 101, as has been explained above.

The process described above may not only be used during the production process of Schottky diodes. Also merged PiN-Schottky (MPS) diodes may be produced, using the described method, for example. MPS diodes comprise implanted areas of a different conduction type (e.g. p-type) than the first and second semiconductor regions. These implanted areas may be covered during the implantation step. The mask that is used for covering the structures may then be used for a following lift-off process for creating the metal contact area. A lift-off process generally is a method of creating structures of a target material on the surface of a substrate using a sacrificial material (e.g. Photoresist).

Further, it is possible to affect the barrier height of MESFET (metal-semiconductor field effect transistor) gate contacts in the same way as has been described in connection with reducing the barrier height in Schottky diodes.

Spatially relative terms such as “under”, “below”, “lower”, “over”, “upper” and the like are used for ease of description to explain the positioning of one element relative to a second element. These terms are intended to encompass different orientations of the device in addition to different orientations than those depicted in the figures. Further, terms such as “first”, “second”, and the like, are also used to describe various elements, regions, sections, etc. and are also not intended to be limiting. Like terms refer to like elements throughout the description.

As used herein, the terms “having”, “containing”, “including”, “comprising” and the like are open ended terms that indicate the presence of stated elements or features, but do not preclude additional elements or features. The articles “a”, “an” and “the” are intended to include the plural as well as the singular, unless the context clearly indicates otherwise.

Although present embodiments and its advantages have been described in detail, it should be understood that various changes, substitutions and alterations can be made herein without departing from the spirit and the scope of the invention as defined by the appended claims. With the above range of variations and applications in mind, it should be understood that the present invention is not limited by the foregoing description, nor is it limited by the accompanying drawings. Instead, the present invention is limited only by the following claims and their legal equivalents.

What is claimed is:

1. A method for processing a semiconductor surface, the method comprising:
irradiating a surface of a semiconductor with ions of a first gas type for cleaning the surface; and
implanting ions of a second gas type in a region below the surface of the semiconductor for creating defects in the region below the surface,
wherein the irradiating and the implanting are performed within a same chamber.

2. The method of claim 1, wherein the first gas type comprises argon, neon or krypton.

3. The method of claim 1, wherein the second gas type comprises nitrogen, phosphine or borane.

4. The method of claim 1, wherein the region in which the ions of the second gas type are implanted forms an additional layer having a thickness between 0.1 nm and 5 nm.

5. The method of claim 1, further comprising:
applying a metal layer on the surface of the semiconductor so as to form a Schottky contact between the metal layer and the semiconductor.

6. The method of claim 5, wherein the region in which the ions of the second gas type are implanted forms an additional layer, and wherein the additional layer is configured to reduce the Schottky barrier height between the metal layer and the semiconductor.

7. The method of claim 5, wherein the metal layer comprises tungsten, titanium, molybdenum or chromium.

8. The method of claim 1, further comprising:
heating the semiconductor during at least one of the irradiating and the implanting.

9. The method of claim 1, further comprising:
igniting a plasma in the chamber for providing the first gas type ions and the second gas type ions.

10. The method of claim 1, further comprising:
accelerating the first gas type ions and the second gas type ions in a direction of the semiconductor.

11. The method of claim 10, wherein the first gas type ions and the second gas type ions are accelerated in the direction of the semiconductor by providing an alternating electric field in the chamber.

12. The method of claim 11, wherein the electric field alternates at a frequency of 13.56 MHz.
